(19) United States
(12) Patent Application Publication
(10) Pub. No.: US 2025/0338593 A1
(43) Pub. Date: Oct. 30, 2025

(54) QUBIT DEVICE COMPRISING FERROMAGNETIC CONTROL GATES

(71) Applicant: ECOLE POLYTECHNIQUE FEDERALE DE LAUSANNE (EPFL), Lausanne (CH)

(72) Inventors: Fabio BERSANO, Lausanne (CH); Mihai Adrian IONESCU, Lausanne (CH); Michele GHINI, Lausanne (CH); Eloi COLLETTE, Lausanne (CH)

(73) Assignee: ECOLE POLYTECHNIQUE FEDERALE DE LAUSANNE (EPFL), Lausanne (CH)

(21) Appl. No.: 18/647,935

(22) Filed: Apr. 26, 2024

(51) Int. Cl. H01L 29/423; H01L 29/12; H01L 29/49; H01L 29/775

(52) U.S. Cl. CPC H10D 64/519; H10D 30/43; H10D 62/813; H10D 64/665

(57) ABSTRACT

A qubit device according to one aspect comprises: a semiconductor substrate; an elongate confinement arrangement; a first dielectric placed between the semiconductor substrate and the confinement arrangement to electrically separate the longitudinal confinement arrangement from the semiconductor substrate; a second dielectric longitudinally at least partially electrically insulating the confinement arrangement; a set of control gates arranged longitudinally along the confinement arrangement and separated from the confinement arrangement by the second dielectric. The control gates are configured to define one or more quantum dots in the confinement arrangement. A respective quantum dot is suitable for holding a spin qubit. The control gates comprise a set of first types of control gates and a set of second types of control gates arranged alternatingly along the confinement arrangement. The first types of control gates are ferromagnetic gates.

### TECHNICAL FIELD

The present invention relates to a spin qubit device comprising first and second types of control gates arranged alternatingly, and in which the first types of control gates are ferromagnetic control gates. The present invention also relates to a method of operating the qubit device.

### BACKGROUND OF THE INVENTION

Fundamental units of quantum information can be encoded in localized spin states within semiconductors. Electron and hole spin qubits have been showcased in diverse semiconductor heterostructures, initially in materials such as gallium arsenide (GaAs) and silicon-germanium (SiGe). Nevertheless, in III-V compounds, the hyperfine interaction between electron and nuclear spins in the host crystal often results in short and inhomogeneous dephasing times that impact the operation of qubits. Natural silicon provides a solution to address this issue by offering a weaker hyperfine interaction, due to the low percentage (4.7%) of ²⁹Si atoms, the only stable isotope with a non-zero nuclear spin. Furthermore, silicon wafers are by definition compatible with complementary metal-oxide-semiconductor (CMOS) technology processes, facilitating a seamless integration of complex arrangements of interconnected spin qubits. Two fundamental problems arise in large-scale integration of qubits: scalability and addressability. Linear arrays and two-dimensional (2D) architectures have been proposed and experimentally validated with up to 6 and 9 qubits. While a 2D architecture proves more fitting for expansive networks, it necessitates depletion gates, also known as confinement gates, to induce one-dimensional (1D) confinement, a role that is naturally fulfilled by etched structures, such as silicon nanowires. Especially for the case of electron spin qubits, the need for depletion gates and micromagnet integration puts stringent restrictions on layout level when scaling up, increasing the complexity of gating layers.

Ferromagnets have been extensively used for electron dipole spin resonance (EDSR) for many years. However, the vast majority of works involve bulky designs in the micrometer range. US2022/0083890 discloses a qubit device having barrier gates and plunger gates arranged alternatingly, but in this case nanomagnets are disposed on top of the multi-gate structure, as an additional separated layer. This has the disadvantage of making the fabrication process more complex while having the nanomagnets far away from the semiconductor substrate, leading to low magnetic driving gradients, and therefore low Rabi frequency.

### SUMMARY OF THE INVENTION

It is an object of the present invention to overcome at least some of the problems identified above related to qubit devices. The present invention thus proposes a qubit device based on one or more arrays of qubits where the ferromagnetic property of gates, such as cobalt gates, can be combined with an active direct current (DC) and radio frequency (RF) driving in operation, with a 2D confinement provided by ultra-thin silicon-on-insulator (SOI) nanowires, for instance.

According to a first aspect of the invention, there is provided a qubit device as recited in claim 1.

According to a second aspect of the invention, there is provided a method of operating the qubit device as recited in claim 22.

Other aspects of the invention are recited in the dependent claims attached hereto.

The present invention involves the integration of ferromagnetic nanosized electrical gates to define quantum dots into a semiconductor for spin qubit applications. This architecture enhances both driving and addressability of spin qubits by shaping the magnetic field gradients surrounding the quantum dots, while minimizing decoherence fields responsible for the loss of quantum information. By exploiting both electrical and ferromagnetic properties of gates, the proposed design significantly reduces the footprint of magnet integration, with a minimized dot-to-magnet distance. This innovation paves the way to large-scale integration of quantum dots and spin qubits with unprecedented magnetic control and scalability.

Furthermore, the proposed qubit device is robust against magnet misalignment and is suitable for cross-bar addressing of qubits. The incorporation of the ferromagnetic gates as suggested here can also be extended to 2D architectures, assuming a design optimized for magnetic driving gradients is used. As the proposed architecture is based on SOI substrates, it is compatible with localized back-gate biasing for noise reduction and dynamic tuning of the threshold voltage.

In the following detailed description, we describe the integration of cobalt as the last gating layer as well as the fabrication of a proof-of-concept device with its experimental electrostatic characterization. In support of the experimental results, we report micromagnetic simulations data supporting the computed magnetic driving and decoherence gradients generated by the ferromagnetic layer under different external magnetic field conditions.

### BRIEF DESCRIPTION OF THE DRAWINGS

Other features and advantages of the invention will become apparent from the following description of non-limiting example embodiments, with reference to the appended drawings, in which:

FIG. 1 shows an example qubit device in a perspective view with a linear array of multi-gate qubits in an SOI nanowire with ferromagnetic barrier gates and metallic plunger gates arranged alternatingly according to an example embodiment of the present invention;

FIG. 2 is a cross-sectional view of the qubit device of FIG. 1, where the cross section is taken longitudinally along a longitudinal direction of the device;

FIG. 3 is a cross-sectional view of the qubit device of FIG. 1, where the cross section is taken transversely along a transverse direction, which is orthogonal to the longitudinal direction of the device;

FIG. 4 shows a top view of a proof-of-concept device employed to demonstrate the integration of ferromagnetic gates with conventional metallic gates for both electrostatic and magnetic manipulation of electrons within silicon quantum dots;

FIG. 5 is a cross-sectional view of the proof-of-concept device of FIG. 4, where the cross section is taken longitudinally along a longitudinal direction of the device;

FIGS. 6a to 6c show a C-V analysis of MOS capacitors with Cr—Co and Ti—Pd as gating materials, where FIG. 6a shows the average value of the measured total parallel capacitance Cp at high and low frequency compensated for the series resistance of the semiconductor substrate Rs, where FIG. 6b shows a table summing up the metals' work function and total density of traps for the two MOS configurations, and where FIG. 6c shows the computed density of interface traps close to the silicon valence band for the two MOS configurations;

FIGS. 7a to 7d illustrate the electrostatic control of Ti—Pd plunger gates and Cr—Co barrier gates on the nanowire channel with source contact grounded, where FIG. 7a shows pinch-off curves for all gates at room temperature and 10 mK. The subthreshold swing at high temperature and low temperature is respectively SS_{RT}=100 mV/dec and SS_{mK}=11 mV/dec, where FIGS. 7b and 7c show room temperature transfer characteristic of plunger and barrier gates for different biases applied to all remaining gates, Vᵢₙᵥ denoting the voltage applied to all gates not included in the linear sweep, and where FIG. 7d shows room temperature I_{D}-V_{DS} characteristic of the nanowire transistor for different voltages applied to all gates, showing ohmic behavior;

FIGS. 8a to 8c illustrate electrostatic trans-characteristics at 10 mK of Ti—Pd plunger gates and Cr—Co barrier gates controlling one quantum dot in the nanowire channel, where FIG. 8a shows plunger gate characteristic for different biases applied to barrier gates, and where FIGS. 8b and 8c show barrier gate characteristics for different biases (0.7 V-0.85 V) applied to the plunger gate therebetween;

FIG. 9a illustrates electrostatic control of right, central and left ferromagnetic barrier gates on Coulomb blockade oscillations in the two dots of the array, and FIGS. 9b and 9c show Coulomb blockade oscillations for one dot and diamonds measured in the many electrons regime (i.e., strong inversion in between two ferromagnetic barriers).

### DETAILED DESCRIPTION OF THE INVENTION

An embodiment of the present invention will now be described in detail with reference to the attached figures. As utilized herein, “and/or” means any one or more of the items in the list joined by “and/or”. As an example, “x and/or y” means any element of the three-element set {(x), (y), (x, y)}. In other words, “x and/or y” means “one or both of x and y.” As another example, “x, y, and/or z” means any element of the seven-element set {(x), (y), (z), (x, y), (x, z), (y, z), (x, y, z)}. In other words, “x, y and/or z” means “one or more of x, y, and z.” Furthermore, the term “comprise” is used herein as an open-ended term. This means that the object encompasses all the elements listed, but may also include additional, unnamed elements. Thus, the word “comprise” is interpreted by the broader meaning “include”, “contain” or “comprehend”. Identical or corresponding functional and structural elements which appear in the different drawings are assigned the same reference numerals. It is to be noted that the use of words “first”, “second” and “third”, etc. may not imply any kind of particular order or hierarchy unless this is explicitly or implicitly made clear in the context.

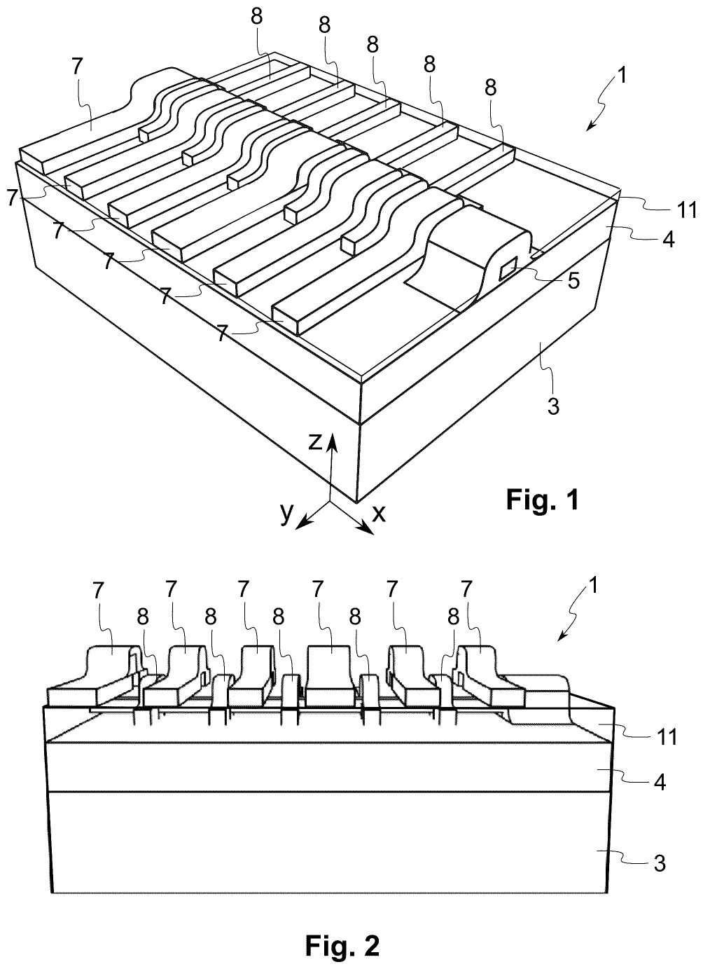

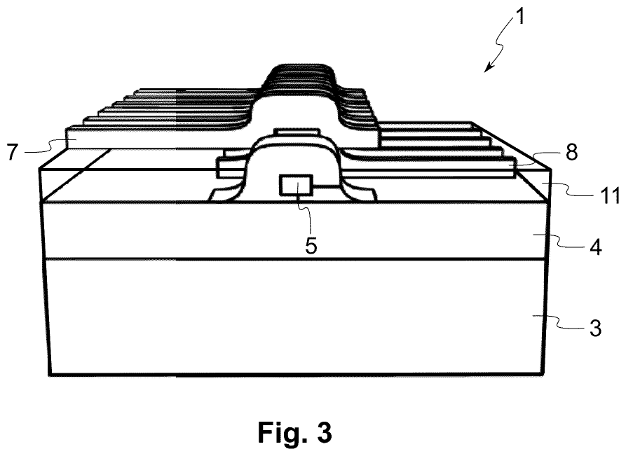

FIGS. 1 to 3 show the qubit device 1 according to an example embodiment of the present invention in different views. The qubit device 1 may for example be used in a quantum computing device. The qubit device 1 comprises a semiconductor substrate layer 3. The substrate 3 may be a silicon layer, e.g. of isotopically purified silicon. Other example materials for the substrate include GaAs and SiGe heterostructures. “x” and “y” indicate a first in-plane direction or dimension and a second in-plane direction or dimension, respectively, with respect to the substrate layer 3. In other words, these two directions define a plane which is parallel to the substrate layer. “z” indicates an out-of-plane direction or dimension, e.g. normal to the substrate layer. Directions x and y May also be referred to as first and second horizontal directions, while direction z may be referred to as a vertical direction. In the following description, direction x is also referred to as a longitudinal or length direction, direction y is referred to as a transverse direction, and direction z is referred to as a height direction.

An insulator or dielectric layer 4, which in this case is a buried oxide layer, is provided directly on top of the substrate layer 3 as shown in the figures. One or more nanowires 5 are arranged on top of the buried oxide layer 3 either directly or separated from the buried oxide layer by another dielectric. If a plurality of nanowires is provided, then they are arranged side by side on top of the buried oxide layer. A nanowire is an elongate nanostructure in the form of a wire with the diameter of the order of a nanometer (10⁻⁹ meters). More generally, nanowires can be defined as structures that have a thickness or diameter constrained to tens of nanometers or less and an unconstrained length. The one or more nanowires extend longitudinally along the longitudinal direction x. In the present example the nanowire 5 is made of silicon.

One of the primary functions of the buried oxide layer is to electrically isolate the active silicon layer (the nanowire in this case) from the substrate. This isolation reduces parasitic capacitances, which can improve the performance of the transistor(s). By isolating the active silicon layer, the buried oxide layer reduces the substrate coupling effects, such as latch-up and noise, which can degrade the performance of integrated circuits. The buried oxide layer also improves the transistor architecture by offering the possibility to integrate a back gate contact for threshold tuning. SOI transistors can thus offer improved performance compared to traditional bulk silicon transistors due to reduced parasitic capacitance and improved control over the transistor channel. This can result in faster switching speeds, lower power consumption, and better radiation tolerance.

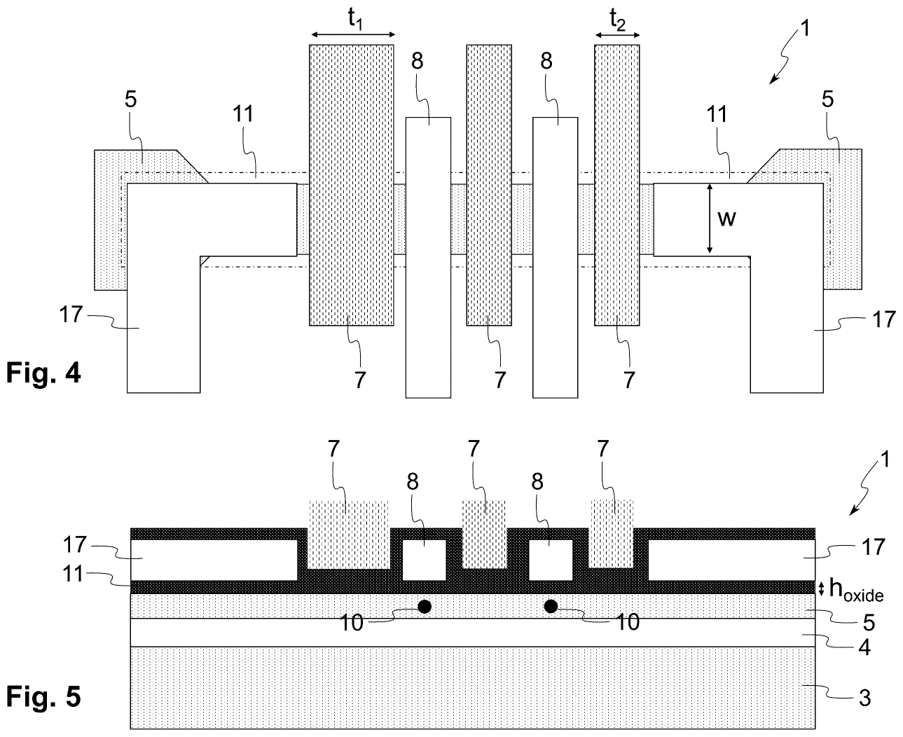

The qubit device 1 comprises a set of control gates 7, 8 along the respective nanowire, and which are configured to define a row of electrostatically confined quantum dots 10 (shown in FIG. 4) in the respective nanowire 5. Gates 7, 8 are referred to as barrier and plunger gates, with the respective function of inducing potential barriers and tuning the chemical potential of quantum dots, and their functions can be interchanged. The row thus extends in parallel to the longitudinal direction x. The qubit device 1 in the example shown in the figures is accordingly suitable to implement a linear or 1D qubit array. As may be appreciated, a quantum computing device may comprise a plurality of such 1D qubit arrays, typically operating independently from each other.

Each quantum dot 10 can hold one or more electrons defining a qubit. It is further contemplated that the principles of the qubit device 1 are compatible with hole-based qubits, although holes due their intrinsic spin-orbit coupling can be controlled without relying on externally engineered magnetic gradients.

The set of control gates of the illustrated qubit device 1 comprises a set of first types of control gates (or first control gates), namely barrier gates 7, and a set of second types of control gates (or second control gates), namely plunger gates 8 arranged alternatingly along the longitudinal direction x. The second types of control gates form a first gate layer with a first distance to the nanowire, and the first types of control gates form a second, different gate layer with a second, different distance to the nanowire, the distance being measured orthogonally to the longitudinal direction. The second distance is greater than the first distance, and the difference between the first and second distances is set by an interlayer insulator, such as an oxide layer, with a thickness optionally ranging from 5 nm to 15 nm.

The quantum dots 10 may be electrostatically confined by the barrier and/or plunger gates 7, 8 along the longitudinal direction x, and by the respective nanowire 5 along the transverse and height directions y and z. The barrier gates 7 and the plunger gates 8 may be biased to cause a depletion of free electrons underneath the barrier gates 7 and to create a respective quantum dot 10 underneath a respective plunger gate 8. The electrochemical potential of each quantum dot 10, and thus the number of accumulated electrons, may be controlled by the respective plunger gate 8. Gate dielectric 11, in this case gate oxide, is used to separate the nanowire from the barrier and plunger gates. The gate oxide thus longitudinally encloses or partially encloses the nanowire. The gate dielectric also forms an interlayer dielectric 11, in this case interlayer oxide, to separate the barrier and plunger gates 7, 8 from each other. The gate oxide 11 is thus used to electrically insulate the different elements from each other.

According to the present embodiment, the barrier gates 7 are made of ferromagnetic material and thus form nanomagnets. Ferromagnetic materials exhibit a spontaneous net magnetization at the atomic level, even in the absence of an external magnetic field. When placed in an external magnetic field, ferromagnetic materials are strongly magnetized in the direction of the field. In other words, the term ferromagnetism is used for any material that could exhibit spontaneous magnetization: a net magnetic moment in the absence of an external magnetic field, i.e., any material that could become a magnet. In the present example, the barrier gates are made or partially made of cobalt and optionally having an adhesion layer between the cobalt part and the gate oxide as explained later. In the present embodiment, the plunger gates on the other hand may be state-of-the art metal gates, which in this example are made of palladium with an optional thin adhesion layer of titanium as explained later to thereby form Ti—Pd gates. The respective adhesion layer may be considered to be part of the respective gate or it may be considered not to be part of the actual gate.

A respective nanowire system thus forms a multi-gate field-effect transistor (FET), in which one end of the respective nanowire 3 forms a source node or terminal, and the other end of the nanowire 3 forms a drain node or terminal. For this purpose, electrical contacts (not shown in the figures) may be provided at the ends or end regions of the nanowire. The associated barrier and plunger gates 7, 8 collectively form the gates of the multi-gate FET. The respective nanowire system is in this manner configured as a multi-gate FET.

The method of fabrication of the qubit device 1 is next described in more detail. In the context of semiconductor device manufacturing, cobalt Co is considered a CMOS-compatible material. It has been explored as a replacement for traditional interconnect metals, such as tungsten and copper, due to its low electron mean free path, and as a valid alternative for silicide formation in advanced technology nodes. Cobalt interconnects have been successfully integrated for nodes below 100 nm in the middle-of-the-line (MOL) metallization layers, showing more than 2× reduction in via resistance and 5-10× improvement in electromigration. However, instances of extrinsic time-dependent dielectric breakdown have been documented for Co interconnects, prompting the characterization of diffusion barriers. Because of the partial diffusion of chromium Cr into low-k dielectrics interface and reaction with oxygen to form Cr₂O₃, the Cr—Co alloy provides a reliable self-forming diffusion barrier that shows a breakdown voltage two times higher than pure Co. According to the present embodiment, where the barrier gates are made of cobalt or partially made of cobalt for instance, it is here therefore proposed to use an adhesion layer, an in particular Cr as an adhesion layer for the integration of Co gates, with the double function of promoting the adhesion of the metal on the gate oxide and forming a diffusion barrier preventing the formation of CoSi. Moreover, Co oxidizes even at ambient temperature if exposed to oxygen. Thus, by placing an interlayer, in particular a Cr adhesion layer between the Co barrier gates and the gate oxide, it is possible to prevent cobalt oxide grow at this bottom interface, thanks to the chromium barrier between the Co gate and the oxygen-reach gate oxide insulating the semiconductor. In the present embodiment, the adhesion layer is placed at the bottom surface of the respective barrier gate, i.e., at the surface facing the nanowire 5.

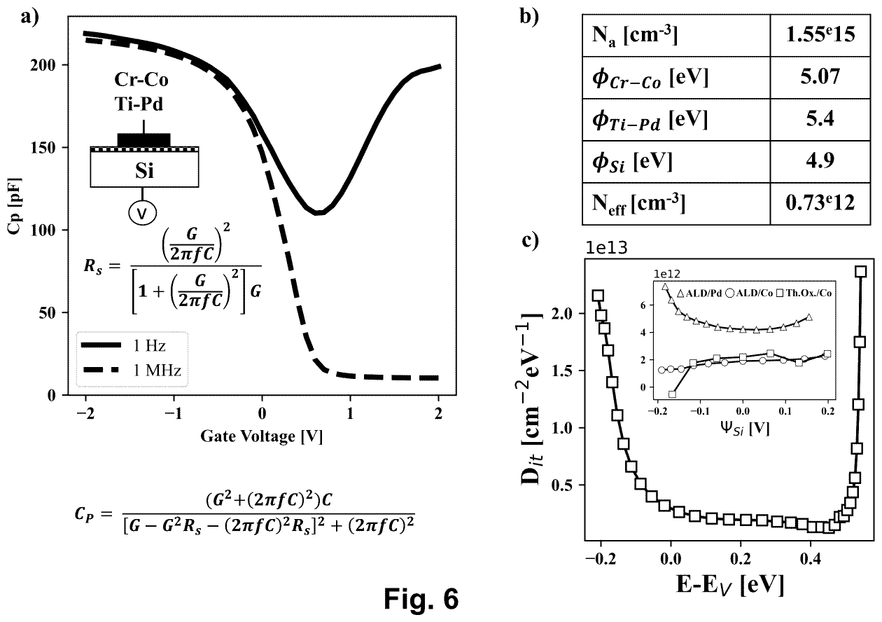

The main requirements for the integration of a metal as a gating layer are chemical stability with a given dielectric to maintain a constant threshold voltage Vth, low high-frequency C-V hysteresis and low interface traps, all of these properties being dependent on the thermal budget of the integration process. As shown in FIG. 6a, we report here the comparison between high frequency (1 MHZ) and quasi-static (1 Hz) C-V measurements of MOS capacitors fabricated with Cr—Co (3-33 nm) and Ti—Pd (3-33 nm) on Al₂O₃ deposited through atomic layer deposition (ALD) at 280° C., this being the same gate-stack as of the fabricated proof-of-concept device schematically shown in FIGS. 4 and 5. The Ti—Pd gating layer has been extensively investigated in the context of spin qubits, commonly exhibiting minimal charge noise and facilitating straightforward evaporation and lift-off processes. Consequently, it serves as a valuable benchmark for comparison with Cr—Co. By comparing the high frequency 1/Cₜₒₜ² plot for different oxide thicknesses, several parameters have been extracted, they are reported in the table in FIG. 6b. The estimated work function of the ferromagnetic gate is a combination of the respective work functions of Cr and Co, as typically reported for heterostructures of thin metallic films. The extracted density of charge traps is relatively high for both Cr—Co and Ti—Pd, this is due to the poor quality of the ALD oxide compared to thermal oxide. The density of interface traps for ALD oxide/Si interface is typically on the order of 10¹² cm⁻2eV⁻¹ and should be independent of the gating layer, assuming chemical stability between the metal and gate oxide. To attain a deeper understanding of the diffusion behavior within the Cr—Co layer and the oxide, the density of interface traps close to the valence band edge of the p-type silicon have been computed for both Ti—Pd and Cr—Co with a high-low frequency comparison method as shown in FIG. 6c. There is no significant distinction observed between the two sets of gates, affirming the chemical stability of the Cr—Co gate at the interface with the gate oxide. However, in real devices, a rapid thermal annealing step in forming gas or pure hydrogen is usually performed to saturate interface traps and dangling bonds before any electrical characterization. In this regard, it is important to notice that any exposure to the ambient atmosphere of a heated sample will result in the partial oxidation of cobalt, and consequent formation of Co(OH2). It is therefore beneficial to employ a capping layer and wait for the complete cool-down of the device in vacuum. According to our experiments, the Cr—Co work function remained stable at 5.0 eV for annealing in forming gas up to 300° C., a thermal budget high enough for most of the end-of-line CMOS processes. However, it is recommended to maintain the annealing temperature below 200° C. to avoid the formation of CoO, which exhibits antiferromagnetic properties that can influence the magnetization of the underlying ferromagnetic cobalt.

The device fabrication and electrical characterization of Co gates are explained in more detail in the following. To demonstrate the co-integration of ferromagnetic gates with standard metal control gates, a double quantum dot proof-of-concept device has been fabricated on an SOI nanowire as schematically illustrated in FIGS. 4 and 5. The top <100> silicon layer was selectively etched down to 18 nm on a 20 nm of buried-oxide, a condition similar to the 22 nm fully depleted (FD) SOI CMOS technology. The notation < > silicon refers to the crystallographic orientation of the wafer's surface. <100> orientation means that the surface of the wafer is aligned with the <100> crystal plane of the silicon crystal. In this example, the width (or thickness) of the nanowire (measured along the transverse direction) ranges from 20 nm to 70 nm, where a narrower layout was chosen to facilitate volume inversion and boost the lever-arm of control gates. Palladium plunger gates 8 with a thin adhesion layer of titanium have been fabricated to control the chemical potential of the quantum dots 10 in the nanowire 5. They alternate with barrier gates 7 made of chromium-cobalt, used to fine-tune tunneling barriers for quantum confinement and drive 2-qubit interactions. In this process-flow, the interlayer oxide consists of Al₂O₃ deposited through ALD. A more convenient approach, particularly in terms of reducing charge noise, would involve utilizing aluminum plunger gates oxidized within a carefully controlled oxygen atmosphere, eliminating the need for any ALD steps. Ohmic contacts (not visible in the figures), which are metal contacts, at both ends of the nanowire 5, have been fabricated with phosphorus-implanted n++ wells contacted with Ti/Pt pads (not visible in the figures) to probe electron conduction through the structure from room temperature to mK with minimal parasitic series resistance. The Ti/Pt pads are at the sides of the qubit device 1, away from the other gates, to provide a good semiconductor-metal contact for the characterization of the device. To isolate the quantum dots 10 from diffused dopants, two lateral inversion gates 17, in this case metal inversion case, made of palladium, for instance, extend the highly conductive implanted regions (located at the opposite ends of the nanowire 5) to the dots area, creating two continuous inversion layers alongside the nanowire 5. In this example work, all layers of gates have been fabricated with e-beam lithography, metal e-beam evaporation and lift-off. However, it is to be noted that the gate layers can be fabricated with any nanometer-scaled lithography technique, such as deep-UV lithography. In the proof-of-concept device 1, the average pitch is 70 nm (measured for example from a first side face of a first barrier gate to a first side face of a second barrier gate) and a barrier gate with a width of 60 nm wide alternates with a pair of gates with a width of 35 nm, to induce different magnetic gradients along the wire and therefore tune the addressability of qubits (as schematically depicted in FIG. 4). More broadly, a first barrier gate with a first width t₁ (measured along the longitudinal direction x) is followed by “X” second barrier gates, with at least a second width t₂, where the first width is greater than the second width, in this case with a width difference of at least 10% or more specifically at least 30%, and where “X” is at least 2, for instance a number comprised between 2 and 10, or more specifically a number comprised between 2 and 5. In this example, the first width is comprised between 10 nm and 110 nm, and more precisely between 40 nm and 80 nm, and the second width is comprised between 5 nm and 65 nm, and more precisely between 15 nm and 55 nm. It is also possible that the second barrier gates or at least some of them have a mutually different width. Furthermore, the width of the first barrier gates does not have to be the same. In this example, the width of the plunger gates is comprised between 5 nm and 65 nm, and more precisely between 15 nm and 55 nm, and optionally the plunger gates have mutually the same width. The proposed architecture is compatible with self-aligned etching processes and cross-bar addressing of quantum dots, a reliable and effective solution for a large-scale integration of spin qubits.

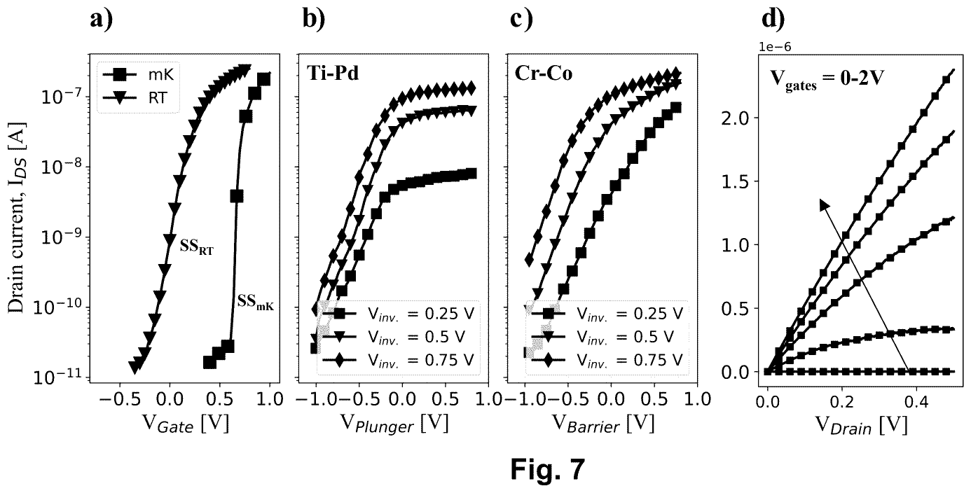

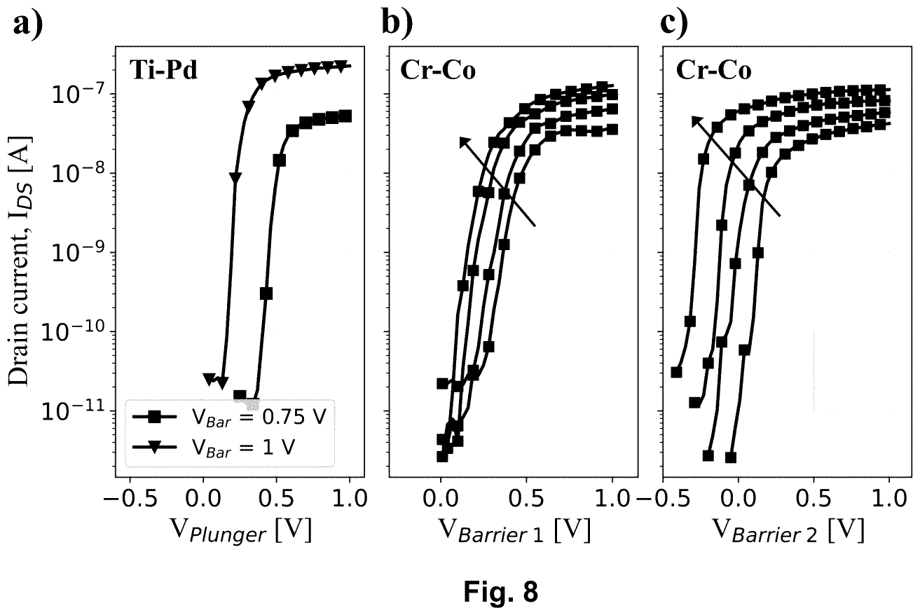

The independent electrical control of the two layers of gates at room temperature is reported in FIG. 7. Each layer exhibits clean pinch-off curves, featuring a subthreshold swing below 100 mV/dec and ohmic behavior of the doped contacts. A threshold voltage mismatch due to the interlayer oxide and difference in work function between the two layers of approximately 500 mV was measured. Finally, the linear threshold voltage dependence of the barrier gates 7 on the plunger's bias (and vice versa) suggests a low inter-gate defectivity, validating the quality of insulation between the layers. As shown in FIG. 8, similar curves have been obtained at 10 mK for the plunger gate 8 and the two barrier gates 7 defining a dot of the array. The discrepancy between the two barrier gates 7 is due to the different width of these gates, engineered to optimize the addressability of qubits.

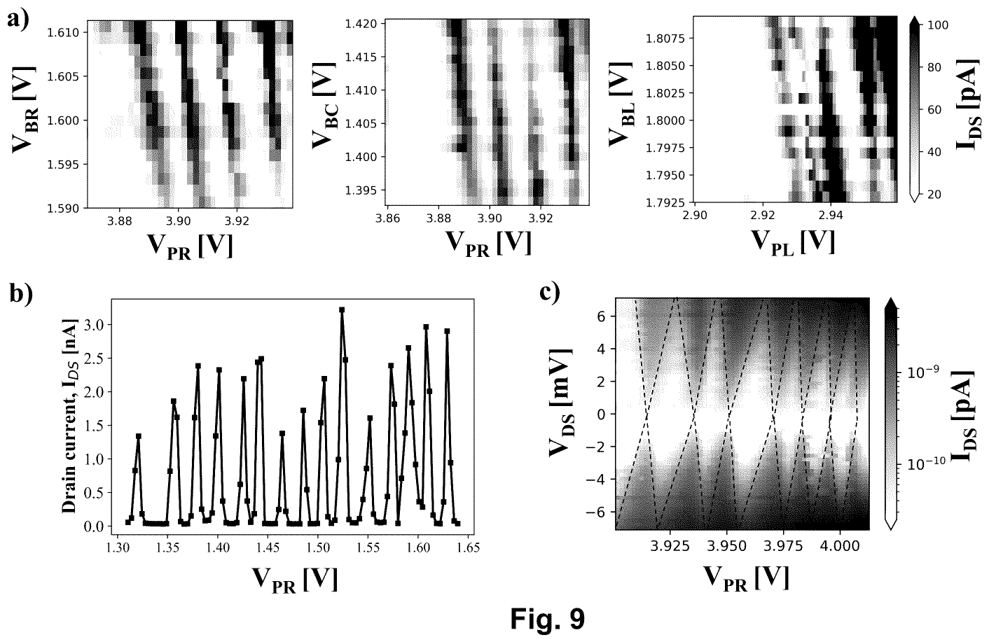

The concept of quantum confinement with the ferromagnetic barrier gates 7 is explained next in more detail. Quantum dots in the many-electron regime have been investigated with DC Coulomb blockade spectroscopy at 10 mK. The independent control of Coulomb current peaks for two quantum dots in the array of three cobalt barrier gates (left, central and right barrier) is shown in FIG. 9. The same figure shows periodic Coulomb oscillations and diamonds (diamond shapes visible in FIG. 9c) for a single dot of the array, obtained by setting the ferromagnetic barrier gates 7 to values well below the threshold voltage and sweeping the plunger gate voltage until reaching strong inversion. A dot capacitance of C_{dot}≈27 af is estimated from the diamonds, giving an equivalent dot radius of r_{dot}≈35 nm in a self-capacitance disc model (C_{dot}=8ϵ_{eq}ϵ₀r_{dot}, where ϵ_{eq}=(ϵ_{Si}+ϵ_{Al2O3})/2), in agreement with the dimension of the nanowire 5. A lever arm of α_{P}≈0.25 eV/V is extracted for the plunger gates on 10 nm of Al₂O₃ (gate oxide), proving a good electrostatic control. It is worth mentioning that a factor of 2x in the lever arm value for both layers could be easily achieved by employing a thin thermal gate oxide (dry-SiO₂) without any additional interlayer oxide, as in the case of nanowires featuring oxidized aluminum gates on SiO₂. The choice of using ALD-Al₂O₃ as an interlayer and gate oxide was in this case dictated by the impossibility of oxidizing the nanowire at chip level and significantly impacted the charge and current noise of the device. However, we performed some preliminary noise measurements on a device where no annealing in forming gas was performed to compare with devices featuring Ti—Pd gates only fabricated under the same conditions. The estimated charge noise is computed from the measured S_{I}(f), given the transconductance gₘ, the charging energy of the dot E_{C} and the lever arm for the plunger gate α_{PG} according to:

$${S}_{C} ( f ) = {α}_{PG}^{2} {\vert \frac{δ {I}_{D S}}{δ {V}_{P G}} \vert}^{- 2} {( \frac{e}{{E}_{C}} )}^{2} {S}_{I} ( f ) ,$$

where, S_{I}(f) is power spectral density of current as a function of frequency and S_{C}(f) is power spectral density of charge noise as a function of frequency, and where, from the Coulomb diamonds,

$${g}_{m} = \frac{δ {I}_{DS}}{δ {V}_{PG}} = 114 nS ,$$

E_{C}=6 meV, and α_{PG}=0.25 eV/V.

At 1 Hz, the extracted S_{C} is below 1e⁻⁶ e²/Hz, which translates into a chemical potential noise comparable with what measured for similar devices with Pd gates, and where annealing in forming gas was performed before the measurements. Consequently, it can be deduced that Cr—Co gates exhibit a minimal impact on noise, as confirmed by the C-V measurements discussed above.

Magnetic driving and addressability of qubits are explained next in more detail. Micromagnetic simulations have been performed with the simulation package MuMax to configure gate geometries according to the teachings of Vansteenkiste, Arne, et al. “The design and verification of MuMax3”, AIP advances 4.10 (2014). The aim was to precisely shape magnetic field gradients at the qubits' location in the presence of an external magnetic field, thereby enhancing both addressability and Rabi frequency. A cell size of 1 nm, zero temperature and cobalt with a saturation magnetization of 1.44 MA/m and exchange stiffness of 21 pJ/m were assumed for the simulations. In this design the main driving gradient is dB_{z}/dx, which is generated by the ferromagnetic barrier gates 7 magnetized along the longitudinal direction x. Due to magnetic shape anisotropy, the barrier gates' magnetization along the longitudinal direction x strongly depends on the external applied magnetic field Bₑₓₜ. A uniform magnetization is reached above Bₑₓₜ=0.5 T. At the qubit location, the driving gradient is above 10 mT/nm, while the decoherence gradient dBₓ/dx has a zero crossing. This is beneficial in terms of qubit fidelity, since a fast-driving region coincides with a charge noise-protected spot along the main displacement direction. We estimate the manipulation speed (i.e., Rabi frequency of the qubits) with

$${f}_{Rabi} = \frac{{γ}_{e}}{h} \frac{{dB}_{z}}{dx} δ x ,$$

where γₑ is the electron gyromagnetic ratio (g-factor of 2), h the Planck's constant and dB_{z}/dx the driving gradient. An oscillation amplitude for the wavefunction (peak-to-peak) of δx=1 nm has been assumed for the computation. Moreover, the expected dephasing rate for the qubit along the direction i∈x, y, z can be estimated by

$${Γ}_{i} = π \sqrt{2} \frac{{γ}_{e}}{h} \frac{{dB}_{x}}{d i} Δ i ,$$

Where we assume Δx=50 pm, Δy=5 μm, and Δz=5 μm. These values approximate well the displacement experienced by the electron wavefunctions along the nanowire 5 due to unwanted electric field fluctuations generated by both barrier and plunger gates 7, 8, in the assumption of a tight confinement in a narrow and symmetric <100> oriented nanowire with a uniform gate oxide 11. Under this condition the nanowire induces a strong quantum confinement along y and z so that Δy and Δz can be considered negligible compared to Δx. Finally, to get a physical insight of the qubit's decoherence experienced in the experimental condition described above, the dephasing time can then be roughly estimated:

$${T}_{2}^{*} = \frac{1}{{Γ}_{x}} + \frac{1}{{Γ}_{y}} + \frac{1}{{Γ}_{z}} .$$

Qubit operation is explained next in more detail. The total magnetic field affecting a qubit within a quantum dot 10 comprises both the fixed external magnetic field Bₑₓₜ and the local magnetic field generated by the barrier gates 7 (which in this example are magnetic nanogates) that alternate along the nanowire 5. When a sufficiently strong magnetic field aligns with the nanowire 5 (e.g., Bₑₓₜ surpassing 0.5 T), the magnetization of the barrier gates 7 aligns in the same orientation x, overriding magnetic-shape anisotropy effects. Interactions between these nanomagnets produce a magnetic gradient dB_{z}/dx perpendicular to the plane defined by the substrate layer 3 or by the buried oxide layer 4, which relies on the dimensions along the longitudinal direction x of the barrier gates (t₁ and t₂ in FIG. 4) and is utilized to manipulate the qubits. Due to variations in the dimensions of the barrier gates 7 (t₁>t₂) forming the quantum dots, distinct qubits engage with diverse driving gradients, resulting in differing spin resonance frequencies. This enables an independent control of single spins along the array of qubits through EDSR. Radio frequency signals applied to either the barrier gate, the plunger gate, or both, control the resonance of spin qubits by matching the Larmor frequency of the spin. These signals induce spatial oscillations along the nanowire direction Δx of the electron wavefunction. The manipulation speed of a qubit (i.e., Rabi frequency) is directly proportional to the magnitude of the driving gradient dB_{z}/dx. As explained above, it can be estimated with:

$${f}_{Rabi} = \frac{{γ}_{e}}{h} \frac{{dB}_{z}}{d x} δ x .$$

With the magnet-dot proximity being extremely close (distance given by the gate oxide height or thickness, h_{oxide} in FIG. 5), high driving gradients dB_{z}/dx exceeding 10 mT/nm are generated, attaining Rabi frequencies surpassing 200 MHz and differences of Larmor frequency between adjacent qubits (addressability) higher than 1 GHz. At the qubit location, the longitudinal gradient dBₓ/dx responsible for spin decoherence has a zero crossing, creating a sweet spot for magnetic and charge noise. Given the tight confinement of the nanowire 5 along the transverse and height directions, displacements along y and z can considered to be negligible compared to 8x. The operation of the qubit device thus comprises at least two main steps, namely the step of applying an external magnetic field allowing the ferromagnetic gates to generate a local magnetic field thereby generating a magnetic gradient substantially orthogonal to a plane defined by the semiconductor substrate allowing the quantum dots to be formed; and the step of applying a respective radio frequency signal to a respective quantum dot through a respective control gate to control a spin state of a respective qubit in the respective quantum dot.

To enable read-out of qubit states, the qubit device 1 may further comprise radio frequency resonators connected to one or more plunger gates 8, in this case to each plunger gate. The resonance frequency of the resonant circuit of the respective resonator will depend on the occupation state of the associated quantum dot 10, and the state of a qubit can be detected by monitoring the reflectance when spin-dependent tunneling between the target qubit and adjacent quantum dots is performed. This inter-dot tunneling modifies the capacitance of the resonator, enabling spin readout.

In the embodiment explained above, the nanowire 5 forms an elongated confinement arrangement. However, instead of using a nanowire, the confinement arrangement may comprise at least two (elongated) confinement gates arranged side by side, as shown in the architecture discussed in US2022/0083890. In this variant, these confinement gates are arranged at mutually opposite sides of the row of quantum dots and extend alongside the same, and where the quantum dots are formed in a semiconductor material underneath the confinement gates.

According to a further variant of the present invention, the roles of the barrier and plunger gates are reversed. More specifically, the plunger gates would be ferromagnetic gates, whereas the barrier gates would be substantially non-magnetic. In this case, the plunger gates would be dimensioned mutually differently according to the teachings above given in connection with the barrier gates.

While the invention has been illustrated and described in detail in the drawings and foregoing description, such illustration and description are to be considered illustrative or exemplary and not restrictive, the invention being not limited to the disclosed embodiments. Other embodiments and variants are understood and can be achieved by those skilled in the art when carrying out the claimed invention, based on a study of the drawings, the disclosure and the appended claims. Further variants may be obtained by combining the teachings of any of the embodiments explained above.

In the claims, the word “comprising” does not exclude other elements or steps, and the indefinite article “a” or “an” does not exclude a plurality. The mere fact that different features are recited in mutually different dependent claims does not indicate that a combination of these features cannot be advantageously used.

1. A qubit device comprising:
a semiconductor substrate;
an elongate confinement arrangement defining a longitudinal direction;
a first dielectric placed between the semiconductor substrate and the confinement arrangement to electrically separate the confinement arrangement from the semiconductor substrate;
a second dielectric longitudinally at least partially electrically insulating the confinement arrangement;
a set of control gates arranged longitudinally along the confinement arrangement and separated from the confinement arrangement by the second dielectric, the set of control gates being configured to define one or more quantum dots in the confinement arrangement, a respective quantum dot being suitable for holding a spin qubit, the set of control gates comprising a set of first types of control gates and a set of second, different types of control gates arranged alternatingly along the confinement arrangement, wherein the first types of control gates are ferromagnetic gates.

2. The qubit device according to claim 1, wherein the first types of control gates are barrier gates, and the second types of control gates are plunger gates.

3. The qubit device according to claim 1, wherein the second types of control gates are substantially non-magnetic.

4. The qubit device according to claim 1, wherein the confinement arrangement is formed by an elongate semiconductor element.

5. The qubit device according to 4, wherein the elongate semiconductor element has a width and height measured perpendicular to the longitudinal direction smaller than 500 nm or smaller than 100 nm.

6. The qubit device according to claim 1, wherein the confinement arrangement comprises two elongate confinement gates arranged side by side and a semiconductor element extending at least in the direction of the elongate confinement gates, and wherein the quantum dots are configured to be defined in the semiconductor element.

7. The qubit device according to claim 1, wherein the first types of control gates are made, or partially made of cobalt, and/or the second types of control gates are made, or partially made of palladium.

8. The qubit device according to claim 1, wherein the qubit device further comprises a respective adhesion layer placed between a respective control gate and the second dielectric for holding the respective control gate on the second dielectric and/or for forming a diffusion barrier between the respective control gate and the second dielectric.

9. The qubit device according to claim 8, wherein a respective first type of adhesion layer is placed between the respective first type of control gate and the second dielectric, and a respective second, different type of adhesion layer is placed between the respective second type of control gate and the second dielectric.

10. The qubit device according to claim 9, wherein the first type of adhesion layer is made of chromium, and/or the second type of adhesion layer is made of titanium.

11. The qubit device according to claim 1, wherein the control gates in the set of first types of control gates have at least two mutually different widths measured along the longitudinal direction.

12. The qubit device according to claim 1, wherein the control gates in the set of first types of control gates comprise a first control gate having a first width followed by at least two second control gates having a second, different width, wherein the width is measured along the longitudinal direction.

13. The qubit device according to claim 12, wherein the first width is greater than the second width.

14. The qubit device according to claim 12, wherein the first width is comprised between 10 nm to 110 nm, or more specifically between 40 nm and 80 nm, and the second width is comprised between 5 nm to 65 nm, or more specifically between 15 nm and 55 nm.

15. The qubit device according to claim 1, wherein the second types of control gates have mutually substantially the same width measured along the longitudinal direction.

16. The qubit device according to claim 1, wherein the second types of control gates form a first gate layer with a first distance to the confinement arrangement, and the first types of control gates form a second, different gate layer with a second, different distance to the confinement arrangement, the distance being measured orthogonally to the longitudinal direction.

17. The qubit device according to claim 16, wherein the second distance is greater than the first distance.

18. The qubit device according to claim 16, wherein the difference between the first and second distances is at least 5 nm, and more specifically at least 15 nm.

19. The qubit device according to claim 1, wherein the qubit device further comprises a first inversion gate extending from a first end of the qubit device to a quantum dot region in a center region of the qubit device, and a second inversion gate extending from a second, opposite end of the qubit device to the quantum dot region, the first and second inversion gates extending longitudinally along the confinement arrangement and separated from the confinement arrangement by the second dielectric to thereby extend a respective electrically conductive doped region at a respective end of the qubit device to the quantum dot region.

20. The qubit device according to claim 19, wherein the second types of control gates and the first and/or second inversion gate(s) form a first gate layer with a first distance to the confinement arrangement, and the first types of control gates form a second, different gate layer with a second, different distance to the confinement arrangement, the distance being measured orthogonally to the longitudinal direction.

21. The qubit device according to claim 1, wherein the qubit device further comprises a respective radio frequency signal generator connected to a respective first type of control gate and/or to a second type of control gate to apply a radio frequency signal to the respective control gate, and/or wherein the qubit device further comprises a respective radio frequency resonator connected to a respective second type of control gate to enable a read-out of qubit state of a respective quantum dot.

22. A method of operating a qubit device comprising:
a semiconductor substrate;
an elongate confinement arrangement;
a first dielectric placed between the semiconductor substrate and the confinement arrangement to electrically insulate the confinement arrangement from the semiconductor substrate;
a second dielectric longitudinally at least partially electrically insulating the confinement arrangement;
a set of control gates arranged longitudinally along the confinement arrangement and separated from the confinement arrangement by the second dielectric, the set of control gates being configured to define one or more quantum dots in the confinement arrangement, a respective quantum dot being suitable for holding a spin qubit, the set of control gates comprising a set of first types of control gates and a set of second types of control gates arranged alternatingly along the longitudinal confinement arrangement, wherein the first types of control gates are ferromagnetic gates,
wherein the method comprises:
applying an external magnetic field allowing the ferromagnetic gates to generate a local magnetic field thereby generating a magnetic gradient substantially orthogonal to a plane defined by the semiconductor substrate allowing the quantum dots to be formed; and
applying a respective radio frequency signal to a respective quantum dot through a respective control gate to control a spin state of a respective qubit.
